(19) United States
(12) Patent Application Publication
(10) Pub. No.: US 2011/0076848 A1
(43) Pub. Date: Mar. 31, 2011

(54) SEMICONDUCTOR PROCESS CHAMBER AND SEAL

(76) Inventors: Amitava Datta, E. Greenwich, RI (US); Peter G. Amos, Essex, CT (US); Dominick G. More, Middletown, CT (US); Kenneth W. Cornett, Ivoryton, CT (US); Jeremy Payne, New Haven, CT (US)

(21) Appl. No.: 12/827,089

(22) Filed: Jun. 30, 2010

Related U.S. Application Data
(60) Provisional application No. 61/221,694, filed on Jun. 30, 2009.

(51) Int. Cl. H01L 21/306; C23C 14/00; F16J 15/02; H01L 21/30; G06F 17/50

(52) U.S. Cl. 438/689; 118/50; 156/345.1; 277/644; 438/758; 703/2; 257/E21.211; 257/E21.215

(57) ABSTRACT

A seal (40) for sealing an interface between a container and a lid of a process chamber. The seal (40) comprises a metallic or polymeric sealing element (50) and an elastomeric sealing element (60) that are arranged to seal the interface in series, with the metallic or polymeric sealing element (50) being situated to encounter processing activity upstream of the elastomeric sealing element (60).

### RELATED APPLICATION

This application claims the benefit of U.S. Provisional Application No. 61/221,694 filed Jun. 30, 2009, which is hereby incorporated herein by reference.

### FIELD OF THE INVENTION

The present invention relates generally to seals and more particularly to seals for use in a substrate processing apparatus.

### BACKGROUND

Many semiconductor manufacturing methods now require processing chambers to create ultra-high-vacuum (UHV—pressures lower than about 10⁻⁷ pascal and/or 10⁻⁹ torr) and/or ultra-high-purity (UHP—total maximum contaminant level of 10 ppm) environments. These manufacturing methods can involve repeated opening and sealing of process chambers so that substrates (e.g., wafers) can be continuously loaded, processed, and then unloaded therefrom. Slow production rates (e.g., caused by long pump-down times), significant equipment downtime (e.g., for seal replacement or interface cleaning) and/or substandard yields (e.g., due to particle generation) are generally viewed as undesirable by semiconductor manufacturers.

### SUMMARY OF THE INVENTION

A seal is provided for sealing the container-lid interface of a semiconductor process chamber. In this seal, a relatively rigid metallic or polymeric element and an elastomeric element are arranged to seal the interface in series, with the metallic or polymeric sealing element being situated to encounter processing activity upstream of the elastomeric element, thereby protecting the elastomeric element from harsh processing conditions while minimizing particle generation. In this manner, the seal can be constructed to achieve ultra high vacuum levels without compromising on cleanliness, and still allow a clamped (rather than bolted) container-lid interface.

### BRIEF DESCRIPTION OF THE DRAWINGS

FIG. 1A is a schematic view of a process chamber comprising a container and a lid, the lid being shown in its load/unload position.

FIG. 1B is a schematic view of a process chamber comprising a container and a lid, the lid being shown in its closed/sealed condition.

FIG. 2A is a close-up view showing a seal installed in a groove in an interface surface of the container when the lid is in its load/unload position.

FIG. 2B is a close-up view similar to FIG. 2A, except that the lid is shown in its sealed condition.

### DETAILED DESCRIPTION

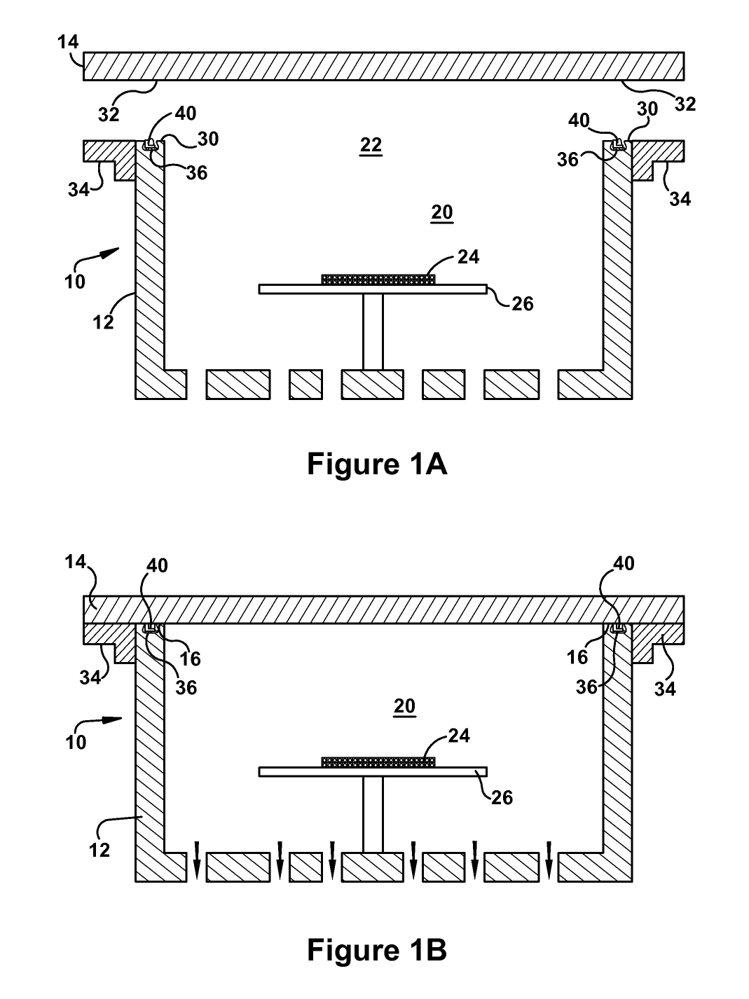

Referring now to the drawings, and initially to FIGS. 1A and 1B, a process chamber 10 comprises a container 12, a lid 14, and an interface 16 therebetween. The container 12 defines a processing space 20 (and an access opening 22 thereinto). The lid 14 is movable between a loading/unloading position (FIG. 1A), whereat the access opening 22 is uncovered, and a sealed condition (FIG. 1B), whereat it seals the access opening 22 into the processing space 20.

The process chamber 10 can be an ultra-high-vacuum (UHV) and/or ultra-high-purity (UHP) chamber which is part of a semiconductor manufacturing process. When the lid 14 is in its load-unload condition, the substrate 24 (e.g., a wafer) can be inserted through the access opening 22 into the processing space 20 and staged on the pedestal 26. Once the lid 14 is moved to its sealed position, the interface 16 is sealed; the substrate 24 can be processed within the container 12. The processing can comprise photo-masking, deposition, oxidation, nitridation, ion implantation, diffusion, and/or etching.

After the wafer-processing step, the vacuum can be released within the processing space 20, and the lid can be converted from its sealed condition to its load-unload condition. The substrate 24 can be withdrawn from the processing space 20 through the access opening 22. These steps can be repeated for the next substrate (e.g., the next wafer in the processing line) and so on.

The container 12 includes an interface surface 30 surrounding the access opening 22 and the lid 14 includes an interface surface 32 seated against the container's interface surface 30 when in its sealed condition. These surfaces 30 and 32 together define the interface 16 between the container 12 and the lid 14. A clamp 34 (or other suitable means) can be provided to brace, lock or otherwise hold the lid 14 against the container 12.

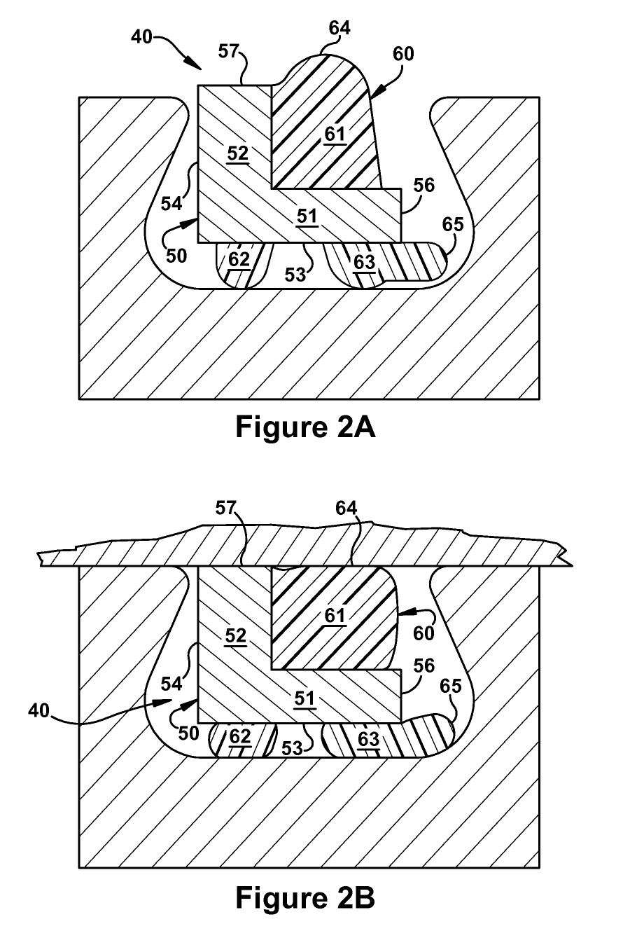

The container's interface surface 30 and/or the lid's interface surface 32 include at least one continuous groove 36. The groove 36 may have a circular plan shape or other plan shape. And as is best seen by referring additionally to FIGS. 2A and 2B, the groove 36 preferably has a dove-tail cross-sectional shape with a wider bottom than top. A seal 40 having a generally ring-like (annular) shape is seated in the continuous groove 36.

The seal 40 generally comprises a metallic or polymeric sealing element 50 and an elastomeric sealing element 60. The metallic or polymeric sealing element 50 can be made from a suitable metal such as aluminum, steel, stainless steel, copper, brass, titanium, nickel, and alloys thereof, or from a suitable polymeric material such as polyether ether ketone (PEEK), polytetrafluoroethylene (PTFE), polyamide (PA), fluoropolymers (PFA), polyetherimide (PEI aka Ultem), nylon or the like, so that the sealing element 50 is relatively rigid and non-elastomeric in comparison to the elastomeric sealing element 60. The elastomeric sealing element 60 can be made from any suitable elastomeric material including fluorocarbon (FKM, FPM), high performance fluoroelastomers (HiFluor), perfluoroelastomers (FFKM, elastomeric PTFE), polyacrylate (ACM), ethylene acrylate (AEM), isobutylene-isoprene (IIR), polychloroprene rubber (CR), ethylene propylene rubber (EPM, EPR, EPDM), fluorosilicone (FVMQ), acrylonitrile-butadiene (NBR), hydrogenated nitrile (HNBR, HSN), polyurethane (AU, EU), silicone (VMQ, PVMQ), and tetrafluoroethylene-propylene (AFLAS registered trademark).

The metallic or polymeric sealing element 50 preferably has an L-shaped cross section with a bottom leg 51 oriented parallel to the floor of the groove and a side leg 52 oriented perpendicular thereto. The legs 51 and 52 together define the floor 53 and the radially inner side wall 54 of the metallic or polymeric sealing element 50. The leg 51 further defines a ledge 55 and a radially outer side wall 56, and the leg 52 further defines a roof 57 and a radially intermediate side wall 58.

The elastomeric element 60 has a roof portion 61, a radially-inner floor portion 62, and a radially-outer floor portion 63. The roof portion 62 is situated in the shelf-like space defined by the ledge 55 and the side wall 58 of the metallic or polymeric sealing element 50. The floor portions 62 and 63 extend downward from the floor 53 of the metallic or polymeric sealing element 50. When the seal 40 is in an uncompressed condition (FIG. 2A), the roof portion 62 has a rounded projection 64 that axially extends beyond the height of the metallic or polymeric sealing element 50 (e.g., its roof 57). The floor portions 62 and 63 each have a bead-like shape, with the outer portion 63 having an extension 65 extending radially beyond the metallic or polymeric sealing element 50 (e.g., its side wall 56).

The metallic or polymeric sealing element 50 and the elastomeric element 60 are arranged to seal a lid interface in series. Specifically, the lid's interfacing surface will first contact the roof portion 61 of the elastomeric member 60 (e.g., its projection 64). This contact will cause compression of the roof portion 61 against the lid and compression of the floor portions 62 and 63 against the floor of the groove. This preliminarily seals the process chamber thereby allowing a vacuum to build and further pull the lid towards the container's interfacing surface. As the container-lid gap decreases, the portions 61-63 of the elastomeric member 60 are further compressed until the height of the roof portion 62 corresponds to the groove's height.

When the seal 40 is installed in the process chamber, and the lid is completely closed, the metallic or polymeric sealing element 50 (e.g., its side wall 54) is situated to encounter processing activity upstream of the elastomeric element. The wider the leg 52, the better protection against, for example, process plasma flow. The metallic or polymeric sealing element 50 is preferably rigid and essentially is not compressed during the closing process. But it is lowered into the groove due to the compression of the floor portions 62 and 63 of the elastomeric member 60. In any event, the metallic or polymeric sealing element 50 functions as a shield to protect the elastomeric element 60 from gas permeation and/or direct impingement of high energy or ions.

The metallic or polymeric sealing element 50 (e.g., its roof 57) may encounter the lid during latter stages of closing depending upon the shape/size of the roof portion 61 and/or its rounded projection 64. The roof 57 of the metallic or polymeric sealing element 50 can have a profile (e.g., flat) to makes parallel contact with the lid's interface surface. The floor portions 62 and 63 of the elastomeric member 60 provide a non-rocking platform for the metallic or polymeric sealing element 50 during the closing process. The inner floor portion 62 provides a vacuum seal along the bottom of the groove and the outer floor portion 63 provides a secondary or redundant seal along this lower path.

The extension 65 on the outer floor portion 63 can perform as a retention feature for the seal 40 once it is installed in the groove. Specifically, for example, if the groove has a dove-tail shape (as shown), the seal 40 cannot be removed therefrom without compression of this extension 65. This retention feature may ease installation and/or reduce seal-pullout when the lid is opened. To perform this role, the extension 65 must result in the radial span of the lower region of the seal 40 having a greater dimension than the radial span of the top of the groove.

The seal 40 can be designed by optimizing parameters including the compressibility of the elastomeric element, the stiffness value of the metallic or polymeric sealing element, the uncompressed height of the elastomeric element, the relative height of the metallic or polymeric sealing element, and/or the initial gap distance between the interfacing surfaces. The optimizing step can comprise, for example, finite element analysis (FEA).

Although the processing chamber 20, the seal 10, the elastomeric element 40, the metallic or polymeric sealing element 50, and/or associated methods have been shown and described with respect to certain embodiments, it is obvious that equivalent alterations and modifications will occur to others skilled in the art. In regard to the various functions performed by the above described elements (e.g., components, assemblies, systems, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function. In addition, while a particular feature of the invention may have been described above with respect to only one or more of several illustrated embodiments, such feature may be combined with one or more other features of the other embodiments, as may be desired and advantageous for any given or particular application.

1. A seal for sealing an interface between a container and a lid of a process chamber, the seal comprising a metallic or polymeric sealing element and an elastomeric sealing element; wherein
the metallic or polymeric sealing element has an L-shaped cross section with a floor leg oriented parallel to the floor of the groove and a side leg oriented perpendicular thereto;
the legs of the metallic or polymeric sealing element together define a floor and a radially inner side wall, the floor leg defines a ledge and a radially outer side wall, and the side leg defines a roof and an intermediate side wall;
the elastomeric element has a roof portion, a radially-inner floor portion, and a radially-outer floor portion; and
the roof portion of the elastomeric element is situated in a shelf-like space defined by the ledge and the intermediate side wall of the metallic or polymeric sealing element, and the floor portions extend axially from the floor of the metallic or polymeric sealing element.

2. A seal as set forth in claim 1, wherein the roof portion has a rounded projection that that axially extends beyond the roof of the metallic or polymeric sealing element when in an uncompressed condition.

3. A seal as set forth in claim 2, wherein the floor portions of the elastomeric sealing element each have a bead-like shape.

4. A seal as set forth in claim 3, wherein the outer floor portion of the elastomeric sealing element has an extension extending radially beyond the radially outer wall of the metallic or polymeric sealing element.

5. A seal as set forth in claim 1, wherein the floor portions of the elastomeric sealing element each have a bead-like shape.

6. A seal as set forth in claim 5, wherein the outer floor portion of the elastomeric sealing element has an extension extending radially beyond the radially outer wall of the metallic or polymeric sealing element.

7. A seal as set forth in claim 1, wherein the metallic or polymeric sealing element is made of aluminum, steel, stainless steel, copper, brass, titanium, nickel, and/or alloys thereof.

8. As seal as set forth in claim 1, wherein the metallic or polymeric sealing element is made of polyether ether ketone (PEEK), polytetrafluoroethylene (PTFE), polyamide (PA), fluoropolymers (PFA), polyetherimide (PEI aka Ultem), and/or nylon.

9. As seal as set forth in claim 1, wherein the elastomeric element is made of an elastomeric material including fluorocarbon, high performance fluoroelastomers, perfluoroelastomers, elastomeric PTFE, polyacrylate, ethylene acrylate, isobutylene-isoprene, polychloroprene rubber, ethylene propylene rubber, fluorosilicone, acrylonitrile-butadiene, hydrogenated nitrile, polyurethane, silicone, and/or tetrafluoroethylene-propylene.

10. A process chamber comprising a container, a lid, and a seal as set forth in claim 1 sealing an interface between the container and the lid; wherein:
the container defines a processing space and an access opening into this processing space;
the lid is movable between a sealed position, whereat it seals the access opening into the processing space, and a loading/unloading position, whereat the access opening is uncovered for insertion/withdrawal of a substrate;
the container includes an interface surface surrounding the access opening and the lid includes an interface surface seated against the container=s interface surface when in its sealed position;
the container's interface surface and/or the lid's interface surface includes at least one groove in which the seal is situated; and
the metallic or polymeric sealing element and the elastomeric sealing element are arranged to seal the interface in series, the metallic or polymeric sealing element being situated to encounter processing activity upstream of the elastomeric sealing element.

11. A process chamber as set forth in claim 10, wherein the groove has a circular plan shape and a dove-tail cross-sectional shape with a bottom region having a wider radial dimension than its top region.

12. A process chamber as set forth in claim 11, wherein the outer floor portion of the elastomeric sealing element has an extension extending radially beyond the radially outer wall of the metallic or polymeric sealing element; and wherein this extension results in the seal having a greater radial dimension than the top region of the groove.

13. A process chamber as set forth in claim 10, wherein the roof portion of the elastomeric member has a rounded projection that that axially extends beyond the roof of the metallic or polymeric sealing element when in an uncompressed condition; wherein the floor portions of the elastomeric sealing element each have a bead-like shape and the outer floor portion of the elastomeric sealing element has an extension extending radially beyond the radially outer wall of the metallic or polymeric sealing element.

14. A method of processing a substrate in the process chamber set forth in claim 10, said method comprising the steps of:
inserting the substrate through the access opening into the processing space when the lid is in its opened position;
moving the lid to its sealed position, wherein said lid-moving step comprises evacuating the processing space and wherein the elastomeric element forms a seal prior to the lid reaching its sealed position;
processing the substrate within the processing space after the lid is in its sealed position;
releasing the vacuum in the processing chamber;
moving the lid from its sealed position and withdrawing the substrate from the processing space.

15. A method as set forth in claim 14, wherein the metallic or polymeric sealing element is not compressed during said lid-moving step.

16. A method as set forth in claim 15, wherein the roof of the metallic or polymeric sealing element contacts the lid prior to the lid reaching its sealed position during said lid-moving step.

17. A method as set forth in claim 16, wherein the roof of the metallic or polymeric sealing element makes parallel contact with the lid.

18. A method of designing the seal set forth in claim 1, said method comprising the step of optimizing design parameters including the compressibility of the elastomeric element, the stiffness value of the metallic or polymeric sealing element, the uncompressed height of the elastomeric element, the relative height of the metallic or polymeric sealing element, and the initial gap distance between the interfacing surfaces.
